(19) United States
(12) Patent Application Publication
(10) Pub. No.: US 2009/0053834 A1
(43) Pub. Date: Feb. 26, 2009

(54) USE OF SCATTEROMETRY FOR IN-LINE DETECTION OF POLY-SI STRINGS LEFT IN STI DIVOT AFTER GATE ETCH

(76) Inventor: Vladimir Alexeevich Ukraintsev, Allen, TX (US)

Correspondence Address: TEXAS INSTRUMENTS INCORPORATED, P O BOX 655474, M/S 3999, DALLAS, TX, 75265, US

(21) Appl. No.: 11/844,060

(22) Filed: Aug. 23, 2007

(51) Int. Cl. H01L 21/66

(52) U.S. Cl. 438/7; 257/E21.529

(57) ABSTRACT

One embodiment of the present invention relates to a method of forming an integrated circuit, comprising forming an STI structure in a semiconductor body, the STI structure having a divot characteristic, performing scatterometry on the STI structure and obtaining signature spectra associated therewith, and continuing fabrication of the integrated circuit when the obtained signature spectra satisfies a predetermined performance specification.

### FIELD OF INVENTION

The present invention relates generally to semiconductor devices and more particularly to methods of using scatterometry for in-line detection of polysilicon strings left in STI divots after the gate etching process in the fabrication of integrated circuits.

### BACKGROUND OF THE INVENTION

In the fabrication of semiconductor devices, isolation structures are formed between active areas in which electrical devices such as transistors, memory cells, or the like, are to be formed. The isolation structures, for example, shallow trench isolation (STI) structures, are typically formed during initial processing of a semiconductor substrate, prior to the formation of such electrical devices.

A MOSFET transistor is a basic building block in a CMOS device, for example, wherein the transistor can be controlled to operate either in a digital or analog manner. In the fabrication of MOSFET transistors, source and drain regions are doped opposite that of a body region or well region in a semiconductor substrate. During the manufacture of shallow trench isolation, divots in the silicon oxide fill are often unintentionally formed. The divots have a divot width, a divot length, and a divot depth, for example. The divots and subsequent deposited polysilicon left within the divots can significantly change MOSFET performance.

The divots and their characterization become even more important as the semiconductor devices further shrink in size. As polysilicon is layered over MOSFET active areas and the oxide fills, for example, the polysilicon when forming a gate will wrap over the actives and fill the divot. The transistors are then no longer the transistors that were designed because of the polysilicon left in the divot changes the MOSFETs performance. Polysilicon strings left after a gate etch in STI divots is a very common defect which can cause electrical shorts between gates, for example.

There are current techniques to measure the divot characteristics; however they are destructive, for example requiring the potting and cross sectioning of the device, which leaves the device inoperable. These techniques are utilized when a problem has already been discovered; at the end stages of workpiece processing, in other words, after many expensive processing acts have been completed, increasing the cost of a failed workpiece. Currently there is no in-line, non-destructive control of the workpiece processing with respect to divot characterization and divot correction.

Therefore a need exists in the semiconductor industry for an improved method to perform divot characterization and divot correction utilizing an in-line process and doing so in a non-destructive manner.

### SUMMARY OF THE INVENTION

The following presents a simplified summary in order to provide a basic understanding of one or more aspects of the invention. This summary is not an extensive overview of the invention, and is neither intended to identify key nor critical elements of the invention, nor to delineate the scope thereof. Rather, the primary purpose of the summary is to present some concepts of the invention in a simplified form as a prelude to the more detailed description that is presented later.

One embodiment is a method of forming an integrated circuit, comprising, forming an STI structure in a semiconductor body, the STI structure having a divot characteristic, performing scatterometry on the STI structure and obtaining signature spectra associated therewith and continuing fabrication of the integrated circuit when the obtained signature spectra satisfies a predetermined performance specification.

Another embodiment is a method of utilizing scatterometry to obtain STI divot data on a semiconductor device in process, comprising creating or simulating a plurality of periodic STI structures, measuring or simulating STI divot data for each of the plurality of periodic STI structures, performing or simulating scatterometry on each of the plurality of periodic STI structures to obtain signature spectra on each of the plurality of periodic STI structures, storing the signature spectra of each of the plurality of periodic STI structures and the associated measured or simulated STI divot data, for each of the plurality of periodic STI structures in an electronic library, performing scatterometry on the semiconductor device in process and collecting resultant signature spectra associated therewith and comparing semiconductor device in process signature spectra to the signature spectra of each of the plurality of periodic STI structures in the electronic library and determining the closest match as an indication of the semiconductor device in process STI divot data.

In yet another embodiment, is a method of detection of polysilicon strings left in STI divots, comprising creating or simulating two dimensional model structures to mimic actual process conditions, performing or simulating two dimensional scatterometry on the two dimensional model structures to obtain database empirical or simulated signature spectra, storing the entire database signature spectra in an electronic library, performing two dimensional scatterometry on an in-process semiconductor device to obtain a device signature spectra, comparing the device signature spectra to the database signature spectra, and taking corrective action on the in-process semiconductor device if unacceptable polysilicon stringers are detected, otherwise continuing with the processing of the in-process semiconductor device.

Yet another embodiment involves a method of detection of polysilicon strings left in STI divots, comprising performing scatterometry on an actual two dimensional in-process semiconductor device to obtain a device signature spectrum, comparing the device signature spectra to empirical or simulated spectra indicating polysilicon, and taking corrective action on the in-process semiconductor device if an unacceptable level of polysilicon is detected, otherwise continuing with the processing of the in-process semiconductor device.

To the accomplishment of the foregoing and related ends, the following description and annexed drawings set forth in detail certain illustrative aspects and implementations of the invention. These are indicative of but a few of the various ways in which the principles of the invention may be employed. Other aspects, advantages and novel features of the invention will become apparent from the following detailed description of the invention when considered in conjunction with the drawings.

### BRIEF DESCRIPTION OF THE DRAWINGS

FIG. 1 is a simplified perspective view illustrating a conventional semiconductor device;

FIG. 2 is a simplified cross sectional view illustrating a partially fabricated conventional semiconductor device with shallow trench isolation structures;

FIG. 3 is an enlarged cross sectional view of a partially fabricated conventional semiconductor device with shallow trench isolation structures as illustrated in FIG. 2;

FIGS. 3A and 4 are flow diagrams illustrating exemplary methods of characterizing STI divots according to aspects of the present invention;

FIG. 5 is a simplified cross sectional view illustrating a partially fabricated conventional semiconductor device with shallow trench isolation structures;

FIG. 6 is a top view of a two-dimensional shallow trench isolation scatterometry structure mimicking an actual two dimensional device; and

FIG. 7 is a flow diagram illustrating yet another exemplary method of characterizing or identifying polysilicon strings in a semiconductor substrate according to one aspect of the present invention.

### DETAILED DESCRIPTION OF THE INVENTION

The present invention will now be described with reference to the attached drawings, wherein like reference numerals are used to refer to like elements throughout. The drawings are not drawn to scale, nor are individual components within the drawings necessarily drawn in scale relative to one another. However, the method is applicable to other processes, for example, a process for forming any suitable digital or analog electronic device, for example, switches, I/O devices, logic devices, analog devices, power IC outputs, switches, inverter switches, and the like that form polysilicon stringers during their manufacture. Furthermore, while the following detailed description is presently contemplated by the inventor for practicing the invention, it should be understood that the description of this embodiment is merely illustrative and that it should not be taken in a limiting sense.

As device sizes shrink, it becomes more and more important to prevent and/or deal with work piece defects in a suitable and efficient manner. One type of defect that the inventor has appreciated is divots formed within an STI. These divots can retain and hold polysilicon that becomes polysilicon strings in a subsequent processing. These polysilicon strings: can cause device failure, unexpected performance, having to discard work pieces, etc.

In order to fully appreciate the various aspects of the present invention, a brief description of at least one embodiment of a semiconductor device including an STI region will be discussed. In the fabrication of semiconductor devices, isolation structures are: formed between active areas in which electrical devices such as transistors, memory cells, or the like, are to be formed. The isolation structures, in this case STI structures, are typically formed during initial processing of a semiconductor substrate, prior to the formation of such electrical devices.

Many companies employ STI technology to isolate electronic devices (e.g., transistors) on an integrated circuit in order to prevent current leakage between the various devices. STI has replaced the traditional LOCOS (local oxidation of silicon) structures, in some applications due to STI providing a more controlled form of electrical isolation. LOCOS structures, in contrast, typically consume larger amounts of space because the oxidation region expands the isolation area laterally in proportion to the depth of the isolation.

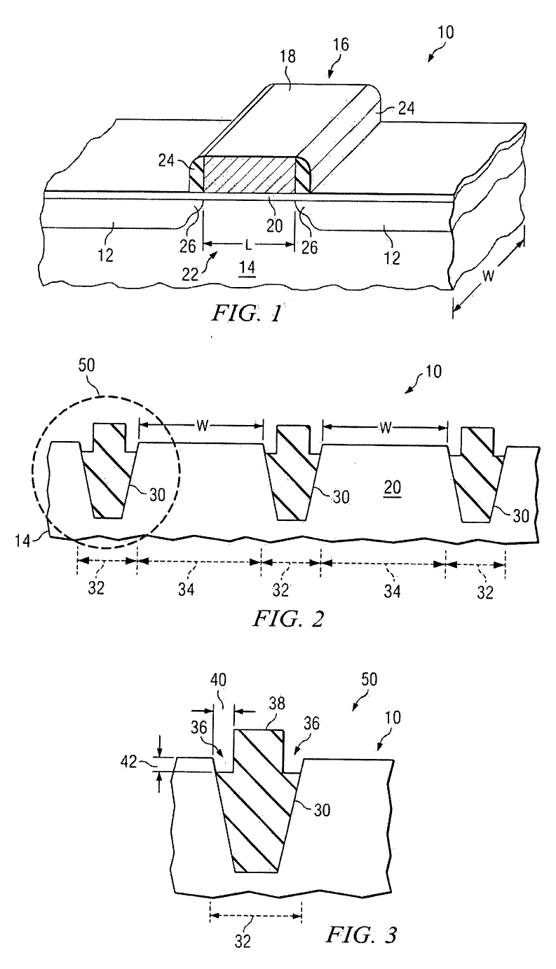

While the methods herein are illustrated and described as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated acts may be required to implement a methodology in accordance with the present invention. Furthermore, the methods according to the present invention may be implemented in association with the operation of devices which are illustrated and described herein (e.g., device 10 in FIG. 1) as well as in association with other devices not illustrated, wherein all such implementations are contemplated as falling within the scope of the present invention and the appended claims.

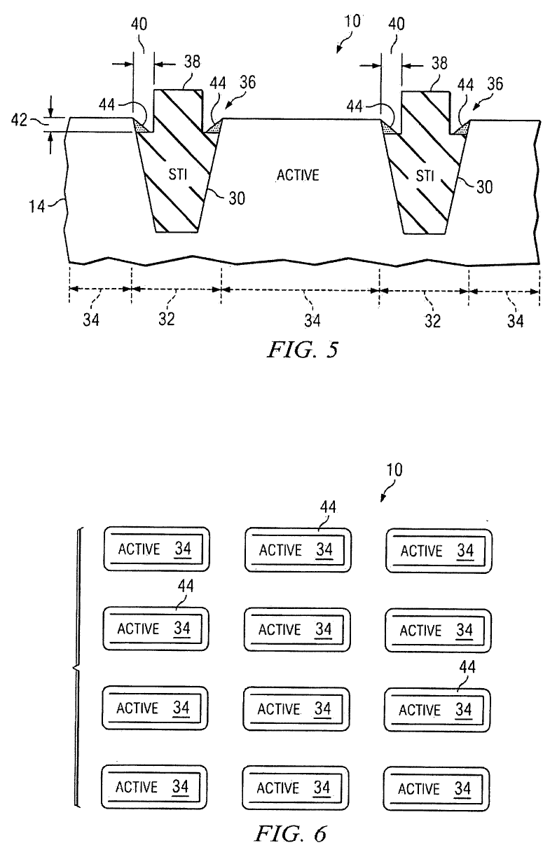

A MOSFET transistor is a basic building block in a CMOS device, for example, wherein the transistor can be controlled, to operate either in a digital or analog manner. In the fabrication of MOSFET transistors, source and drain regions are doped opposite that of a body region or well region in a semiconductor substrate. FIGS. 1-4 discuss the formation of STI divots in a semiconductor devices and a novel method for determining the divot characteristics in-line and in a non-destructive manner in the forming of integrated circuits. FIGS. 5-7 represent polysilicon strings formed within an STI divot and an in-line and non-destructive method for determining if they exist in the device during fabrication of integrated circuits.

As illustrated in FIG. 1, source/drain regions 12 are formed in a semiconductor body 14 of a MOSFET transistor 10, wherein the source/drain regions 12 can be an n-type material and the body region 14 can be a p-type material (an NMOS transistor). A gate structure 16, for example, a polysilicon gate electrode 18 overlying a gate dielectric 20, overlies a channel region 22 of the semiconductor body. Sidewall spacers 24 can reside on lateral edges of the gate structure 16 to facilitate the spacing of extension regions 26 associated with the source/drains 12. Based on the gate structure 16, a distance between the source/drain regions 12 is defined, which is often referred to as a channel length “L”, while a depth of the transistor, or extent in which the transistor extends transverse to the channel, is often referred to as a width “W” of the device

Referring to FIG. 2, a portion of a partially fabricated semiconductor device 10 is illustrated, wherein a plurality of STI structures 30, i.e., isolation structures, are formed in the semiconductor body 14, thereby separating the body into isolation regions 32 and active areas 34, respectively. Subsequently, transistor devices such as MOSFET transistors as illustrated in FIG. 1 can be formed in the active areas 34, wherein a width dimension “W” of the MOSFET transistors extends between the isolation structures 30 as illustrated. As MOSFET transistor scaling continues, the distance “W” between the isolation structures decreases. As transistor devices are scaled down to improve device density, both the width “W” and the channel length “L” dimensions are reduced, giving rise to various fabrication and device performance issues.

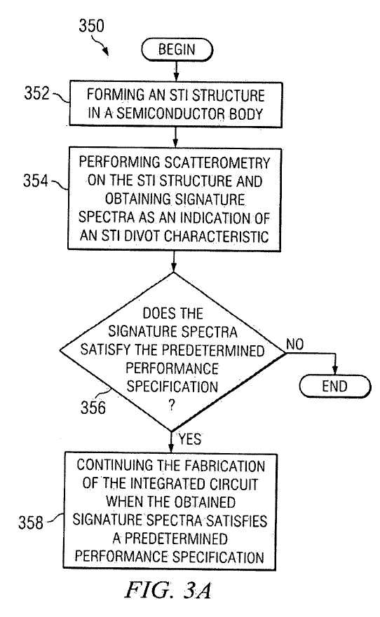

As illustrated in FIG. 3, is an enlarged side view 50 of a portion of the partially fabricated semiconductor device 10, as illustrated in FIG. 2. During the manufacture of shallow trench isolation 30, divots 36 in the silicon oxide fill 38 are often unintentionally formed. The STI divots 36 illustrated have a divot width 40 and a divot depth 42. The divots 36 and subsequent polysilicon processing, for example, involving the divots 36 can significantly change MOSFET performance. STI divots and the formation thereof are well known by those of ordinary skill in the art.

The divots 36 are even more important as the semiconductor devices further shrink in size. As polysilicon (not shown) is layered over the oxide fill 38, for example, the polysilicon when forming a gate will wrap over the active and the oxide fill 38 and fill or partially fill the divot 36. The subsequently formed transistor is then no longer the transistor that was designed/intended because of the polysilicon left in the divot 36. Polysilicon strings are often left after gate etch, for example, in STI divots and this common defect can cause electrical shorts between gates. This becomes more critical as the devices are reduced in size, as discussed supra because the divot 36 becomes a larger contributing factor to errors in the semiconductor device.

Now referring to FIG. 3A, an exemplary method 350 is shown for using scatterometry in the formation of an integrated circuit with STI. The method begins at 352 with forming an STI structure in a semiconductor body wherein the STI structure has STI divots with various divot characteristics. The STI divot characteristics are well know in the art comprise STI divot width, STI divot length, STI divot height and STI divot surface roughness, for example. At 354 scatterometry can be performed on the STI structure to obtain signature spectra associated with the STI structure as an indication of a STI divot characteristic. At 356 it is determined if the signature spectra of the STI device satisfies a predetermined performance specification. If the signature spectra of the STI device satisfies a predetermined performance specification the process continues to 358, wherein the fabrication of the integrated circuit continues, otherwise the process ends.

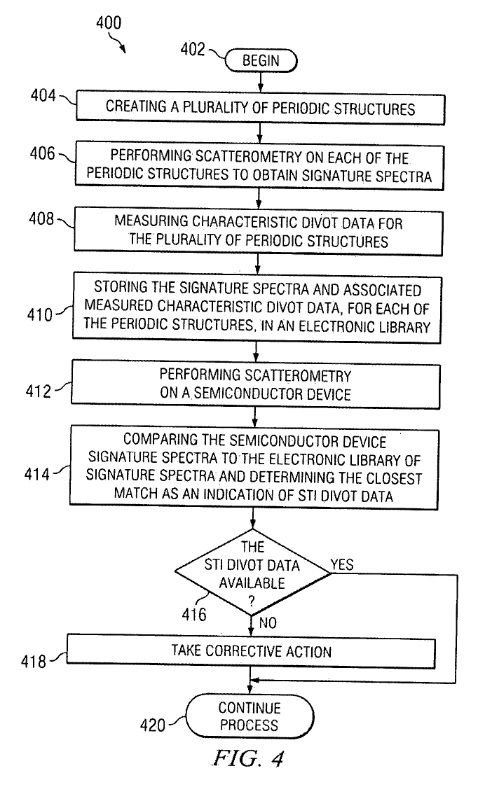

Referring to FIG. 4, an exemplary method 400 is illustrated for utilizing scatterometry to determine STI divot metrology in accordance with one or more aspects of the present invention. It will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated acts may be required to implement a methodology in accordance with the present invention. Furthermore, the methods according to the present invention may be implemented in association with the formation and/or processing of structures illustrated and described herein as well as in association with other structures not illustrated herein. The process of scatterometry, for example can be utilized to determine the characteristics of work piece characteristics other than STI divots and all such work piece characteristics are contemplated herein. In addition, the scatterometry process can be used on other devices, for example, switches, I/O devices, logic devices, analog devices, power IC outputs, inverter switches, and the like.

The process begins at 402 of FIG. 4, wherein a plurality of periodic STI structures are created or simulated, for example at 404. It will be appreciated that the number of the periodic STI structures is greater than two and can be in the hundreds or thousands. Each of the periodic STI structures can be numbered or indexed and scatterometry can be performed or simulated on the periodic STI structures at 406 to obtain associated signature spectra, for example. Any appropriate process, materials and scatterometry procedure can be employed to determine the signature spectra of the periodic STI structures, as are well known to those of ordinary skill in the art.

At 408 each of the periodic STI structures with the signature spectrum obtained empirically or by simulation can have its characteristic divot data measured or simulated using common destructive testing or analysis, for example. The periodic STI structure can be potted in epoxy and cross sectioned using standard techniques and then TEM can be used to determine the divot length, divot width and divot depth, for example. At 410 the measured or simulated characteristic divot data and the signature spectra associated with the divot data, for each of the periodic STI structures, can be stored in an electronic library as an associated data set (e.g., data set (1): signature spectrum for periodic STI structure (1), pivot characteristics for periodic STI structure (1)). It is to be understood that the electronic library comprises raw data, STI divot data, signature spectra for the periodic STI structures, signature spectra for empirical or simulated devices, indexing data, software, hardware, and the like. Again there can be hundreds or thousands of these data sets in the library that associate a specific signature spectra, empirical or simulated with a measured set of STI divot data.

At 412, scatterometry is performed on the semiconductor device going through a given process. The scatterometry can be performed on an intermittent or a continual basis, depending on the process underway.

At 414, the semiconductor device signature spectrum is compared to the electronic library of signature spectra and the closest match is automatically determined, as an indication of the STI divot characteristics (e.g., STI divot width, STI divot depth, surface roughness, etc.). It is to be appreciated that various sorting and optimization techniques can be employed determining the closest match and all such techniques are contemplated herein. At 414, an operator (of an actual fabrication process) can determine if the STI divot is too large or an in-line process automatically determines if the divot characteristic measurements are out of specification, for example. If the divot characteristics are out of an acceptable range (i.e., unacceptable), corrective action can be taken at 418, otherwise the process continues at 420, as illustrated. If the corrective action is performed at 418 then the process can again continue at 420. The corrective actions may include additional processing to remove or reduce the divot, discarding the device, and the like.

Referring to FIGS. 5 and 6, a portion of a partially fabricated semiconductor device 10 as illustrated in FIGS. 2 and 3, for example, is illustrated, wherein a plurality of STI structures 30, i.e., isolation structures, are formed within the semiconductor body 14, which separate the body 14 into isolation regions 32 and active areas 34, respectively. Subsequently, transistor devices such as transistors illustrated in FIG. 1, for example can be formed in the active areas 34. During the manufacture of shallow trench isolation 30, divots 36 in the silicon oxide fill 38 are often unintentionally formed. The divots 36 illustrated have a pivot width 40 and a pivot depth 42. The divots 36 can retain polysilicon 44 after polysilicon processing, for example, which can significantly change MOSFET performance.

The divots 36 and the remaining polysilicon 44 are an even more important defect as the semiconductor devices further shrink in size. As polysilicon is layered over the active 34 and the oxide fill 38, for example, the polysilicon when forming a gate (not shown) will wrap over the active 34 (and the oxide fill 38) and fill the divot 36. The subsequently formed transistor is then no longer the transistor that was designed because of the remaining polysilicon 44 in the divot 36. The polysilicon strings 44 are often left after gate etch, for example, in STI divots 36 and this is a very common defect which can cause electrical shorts between gates. Again, this becomes more critical as the devices are reduced in size, as discussed supra because the polysilicon string 44 becomes a larger contributing factor to errors in the semiconductor device.

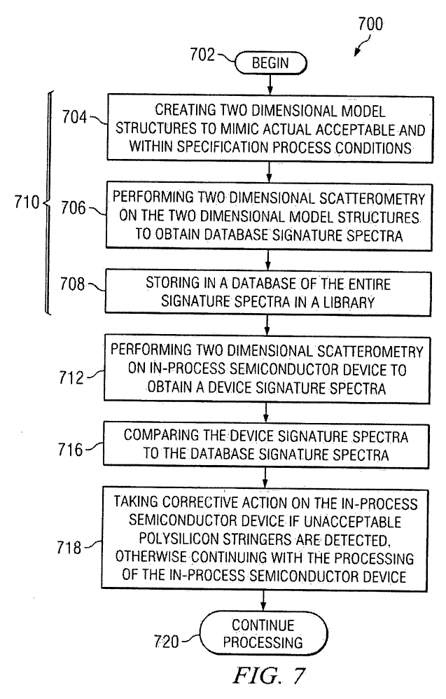

Referring now to FIG. 7, an exemplary method 700 is illustrated for determining if polysilicon strings are present in a semiconductor device in accordance with one or more aspects of the present invention. It will be once again appreciated that the present invention is not restricted by the illustrated ordering of acts or events. Some acts or events may occur in different orders and/or concurrently with other acts or events apart from those illustrated and/or described herein, in accordance with the invention. In addition, not all illustrated acts or events may be required to implement a methodology in accordance with the present invention. Furthermore, the methods according to the present invention may be implemented in association with the formation and/or processing of structures illustrated and described herein as well as in association with other structures not illustrated.

The process 700 begins at 702, wherein at 704 of FIG. 7, two dimensional model structures can optionally be created or simulated to mimic actual devices that are acceptable and within specification. The model structures can be semiconductor devices that lack the polysilicon strings 44 shown in FIGS. 5 and 6. The methodology continues at 706, where optionally scatterometry is performed or simulated on the model structures wherein the scatterometry techniques are well known by those of ordinary skill in the art. The optional process at 706 results in signature spectrum being obtained or simulated for each of the model structures, wherein the spectra signature and the model structure data can be stored as a set. All of the data obtained or simulated at 706 is optionally stored in a library at 708.

In an alternate embodiment at 710 acts 704, 706 and 708 are eliminated from the process, for example. At 712 of FIG. 7 in a first embodiment scatterometry can be performed on two dimensional an in-process semiconductor device to obtain a device signature spectrum. In the first embodiment (e.g., including 704, 706 and 708), the device spectra obtained at 712 can be compared to the database signature spectra at 716. In another second embodiment, (e.g., excluding 704, 706 and 708) the in-line device spectrum can be analyzed (for example, compared to an empirical spectrum of the in-line device without a polysilicon string) to determine the material properties of the in-line device and whether polysilicon remains in the device. It should be apparent to those of ordinary skill in the art that other scatterometry analysis techniques are contemplated with this invention.

The exemplary method 700 continues at 718, for example, wherein if an unacceptable polysilicon string is detected than corrective actions can be taken to repair the in-process device. The repair techniques are widely known in the art by those of ordinary skill. If the in-process device is deemed acceptable at 718 the processing continues at 720, for example.

Although the invention has been illustrated and described with respect to one or more implementations, equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising.”

What is claimed is:

1. A method of forming an integrated circuit, comprising:
forming an STI structure in a semiconductor body, the STI structure having a divot characteristic;
performing scatterometry on the STI structure and obtaining signature spectra associated therewith; and
continuing fabrication of the integrated circuit when the obtained signature spectra satisfies a predetermined performance specification.

2. The method of claim 1, wherein corrective action is taken on the integrated circuit when the obtained signature spectra fails to satisfy a predetermined performance specification.

3. The method of claim 2, wherein the predetermined performance specification is generated comprising:
creating or simulating a plurality of periodic STI structures;
wherein at least two of the periodic STI structures have a divot characteristic different from one another;
measuring or simulating STI divot data for each of the plurality of periodic STI structures;
performing or simulating scatterometry on each of the plurality of periodic STI structures to obtain signature spectra on each of the plurality of periodic STI structures; and
storing the signature spectra of each of the plurality of periodic STI structures and the associated measured or simulated STI divot data, for each of the plurality of periodic STI structures; in the performance specification.

4. A method of utilizing scatterometry to obtain STI divot data on a semiconductor device in process, comprising:
creating or simulating a plurality of periodic STI structures;
wherein at least two of the periodic STI structures have a divot characteristic different from one another;
measuring or simulating STI divot data for each of the plurality of periodic STI structures;
performing or simulating scatterometry on each of the plurality of periodic STI structures to obtain signature spectra on each of the plurality of periodic STI structures;
storing the signature spectra of each of the plurality of periodic STI structures and the associated measured or simulated STI divot data, for each of the plurality of periodic STI structures, in an electronic library;
performing scatterometry on the semiconductor device in process and collecting resultant signature spectra associated therewith; and
comparing semiconductor device in process signature spectra to the signature spectra of each of the plurality of periodic STI structures in the electronic library and determining the closest match as an indication of the semiconductor device in process STI divot data.

5. The method of claim 4, wherein the STI characteristic comprises an STI divot width, an STI divot depth, an STI divot surface roughness, and an STI divot length.

6. The method of claim 4, wherein corrective action is taken on the semiconductor device in process if the STI divot data on the semiconductor device is out of a predetermined specification range.

7. The method of claim 4, wherein processing of the semiconductor device in process continues if the STI divot data on the semiconductor device is within a predetermined specification range.

8. The method of claim 4, wherein the STI divot data comprises: an STI divot width, an STI divot depth, an STI divot surface roughness, and an STI divot length.

9. The method of claim 4, wherein the plurality of the periodic STI structures comprises two or greater.

10. The method of claim 4, wherein the performing scatterometry comprises:
directing light waves at the periodic STI structure or at the semiconductor device or both; and
measuring light waves diffracted from the periodic STI structures or the semiconductor device or both.

11. The method of claim 4, wherein the scatterometry is performed with a technique comprising a spectrometry, spectral ellipsometry, spectral reflectometry, and single wavelength variable angle reflectometry to obtain the signature spectra.

12. The method of claim 4, wherein the method is in-line and non-destructive to the semiconductor device.

13. The method of claim 4, wherein the electronic library comprises the STI divot data, the signature spectra on the plurality of periodic STI structures, signature spectra on the semiconductor devices in process, index numbers, and software.

14. A method of forming an integrated circuit, comprising:
creating or simulating a plurality of model structures to mimic actual structures relating to polysilicon strings in STI divots;
performing or simulating scatterometry on each of the plurality of model structures to obtain model structure signature spectra;
storing the model structure signature spectra in a library;
performing scatterometry on an in-process semiconductor device having an STI structure formed therein to obtain a device signature spectra; and
comparing the device signature spectra to the database signature spectra.

15. The method of claim 14, wherein corrective action is taken on the in-process semiconductor device if unacceptable polysilicon strings are detected.

16. The method of claim 14, wherein processing continues on the in-process semiconductor device if unacceptable polysilicon strings are not detected.

17. The method of claim 14, wherein the detection of the polysilicon strings on the in-process semiconductor device is performed in-line and in a non-destructive manner.

18. The method of claim 14, wherein the performing scatterometry comprises:
directing light waves at the model structures or the semiconductor device or both;
measuring light waves diffracted from the model structures or the semiconductor device or both; and
the model structure is two dimensional.

19. The method of claim 14, wherein the scatterometry is performed using a technique comprising spectrometry, spectral ellipsometry, spectral reflectometry, and single wavelength variable angle reflectometry to obtain the signature spectra.

20. A method of claim 14, wherein detection of polysilicon strings left in STI divots, comprising:
performing scatterometry on an actual in-process semiconductor device to obtain a device signature spectrum; and
comparing the device signature spectra to empirical or simulated spectra of the device knowingly having polysilicon strings.

21. The method of claim 14, wherein corrective action is taken on the actual in-process semiconductor device if an unacceptable amount of polysilicon is detected, otherwise continuing with the processing of the in-process semiconductor device.

22. The method of claim 14, wherein the detection of the polysilicon strings is performed in-line and in a non-destructive manner.

23. The method of claim 14, wherein the performing scatterometry comprises:
directing light waves at the in-process semiconductor device; and
measuring light waves diffracted from the in-process semiconductor device.

24. The method of claim 14, wherein the scatterometry is performed using a technique comprising spectrometry, spectral ellipsometry, spectral reflectometry, and single wavelength variable angle reflectometry to obtain the signature spectra.
